(19) United States
(12) Patent Application Publication
(10) Pub. No.: US 2025/0355478 A1
(43) Pub. Date: Nov. 20, 2025

(54) SIGNAL CONVERSION CIRCUIT

(71) Applicant: ZHUHAI ISMARTWARE TECHNOLOGY CO., LTD., Zhuhai (CN)

(72) Inventors: Anyi YUAN, Zhuhai (CN); Yuanchao LIANG, Zhuhai (CN); Yongzhi XU, Zhuhai (CN)

(21) Appl. No.: 19/283,034

(22) Filed: Jul. 28, 2025

Related U.S. Application Data
(63) Continuation-in-part of application No. PCT/CN2024/091016, filed on Apr. 30, 2024.

(30) Foreign Application Priority Data
Jun. 9, 2023 (CN) 202310682313.9

(51) Int. Cl. G06F 1/26

(52) U.S. Cl. CPC G06F 1/26

(57) ABSTRACT

A signal conversion circuit is provided, relating to the field of universal serial bus power delivery (USB PD) communication technologies. The signal conversion circuit includes a conversion timing generation module, configured to convert an input communication data signal into a plurality of delay control signals; a signal amplitude calibration module; a voltage-mode digital-to-analog conversion module, where an input terminal of the voltage-mode digital-to-analog conversion module is electrically connected to an output terminal of the conversion timing generation module, and the voltage-mode digital-to-analog conversion module is electrically connected to the signal amplitude calibration module; a smoothing filter module, where an input terminal of the smoothing filter module is electrically connected to an output terminal of the voltage-mode digital-to-analog conversion module; and a transmission conversion module, wherein an input terminal of the transmission conversion module is electrically connected to an output terminal of the smoothing filter module.

### CROSS REFERENCE TO RELATED APPLICATION

This patent application is a continuation-in-part of International Patent Application No. PCT/CN2024/091016, filed Apr. 30, 2024, which claims the benefit of and priority to Chinese Patent Application No. 202310682313.9, filed Jun. 9, 2023, each of which is hereby incorporated by reference herein in its entirety.

### TECHNICAL FIELD

The present application relates to the field of universal serial bus power delivery (USB PD) communication technologies, and in particular, to a signal conversion circuit.

### BACKGROUND

During the production of Type-C interfaces, it is necessary to adjust the slope of the biphase mark coding (BMC) signal to meet the eye diagram compliance test for PD communication. In related technologies, the slope of the BMC signal is adjusted by changing the current value. However, conventional slope adjustment methods cannot precisely control the slope at each node along the signal edge. In cases of steep slopes, it is difficult to simultaneously meet the rise time and fall time requirements for eye diagram compliance test, thus making it impossible to pass the eye diagram compliance test for PD communication.

### SUMMARY

The present application is intended to solve at least one of the technical problems existing in the prior art. To address this, the present application proposes a signal conversion circuit, which enables the BMC signal to meet the requirements of eye diagram compliance test and a slope for PD communication. In addition, the signal conversion circuit features a low technical design barrier, offers flexible and simple debugging, and is easy to integrate on silicon wafers, without the need of any off-chip component, thus enhancing market applicability.

According to a first aspect, the present application provides a signal conversion circuit, including:
a conversion timing generation module, configured to convert an input communication data signal into a plurality of delay control signals;
a signal amplitude calibration module;
a voltage-mode digital-to-analog conversion (DAC) module, where an input terminal of the voltage-mode digital-to-analog conversion module is electrically connected to an output terminal of the conversion timing generation module, and the voltage-mode digital-to-analog conversion module is electrically connected to the signal amplitude calibration module and configured to convert the plurality of delay control signals into stepwise ramp signals;
a smoothing filter module, where an input terminal of the smoothing filter module is electrically connected to an output terminal of the voltage-mode digital-to-analog conversion module; and the smoothing filter module is configured to perform smoothing filtering processing on the stepwise ramp signals to obtain a first voltage signal; and
a transmission conversion module, where an input terminal of the transmission conversion module is coupled to an output terminal of the smoothing filter module; and the transmission conversion module is configured to convert the first voltage signal into a BMC transmission signal.

According to the signal conversion circuit provided in the embodiments of the present application, a communication data signal is converted into a plurality of delay control signals, which are further converted into stepwise ramp signals. In this way, a stepwise voltage and slope of the stepwise ramp signals can be adjusted based on actual needs, and a voltage amplitude of a BMC transmission signal can be adjusted based on the signal amplitude calibration module, such that a BMC signal can meet the requirements of eye diagram compliance test and a slope for PD communication. In addition, the signal conversion circuit features a low technical design barrier, offers flexible and simple debugging, and is easy to integrate on silicon wafers, without the need of any off-chip component, thus enhancing market applicability.

According to one embodiment of the signal conversion circuit of the present application, the conversion timing generation module includes:
a plurality of cascaded flip-flops, where a first-stage flip-flop in the plurality of flip-flops is configured to receive the communication data signal; and
a logical combination unit including an input terminal electrically connected to an output terminal of each of the flip-flops, and an output terminal electrically connected to the input terminal of the voltage-mode digital-to-analog conversion module.

According to one embodiment of the signal conversion circuit of the present application, the voltage-mode digital-to-analog conversion module includes:
a series resistor array including a first resistor array, where the series resistor array includes an input terminal connected to a power supply, and an output terminal electrically connected to an input terminal of the signal amplitude calibration module; and
a switch control unit including a first switch array, where a first target switch in the first switch array includes one terminal connected to the power supply and the other terminal connected to the smoothing filter module, a second target switch in the first switch array includes one terminal connected to the output terminal of the series resistor array and the other terminal connected to the smoothing filter module, and a third target switch in the first switch array includes one terminal connected to the smoothing filter module and the other terminal connected to a first target resistor in the series resistor array, where the first target resistor is an nth resistor in the series resistor array, the third target switch is an n-th switch in the switch control unit, n is a positive integer, the first target switch is a first switch in the first switch array, and the second target switch is a last switch in the first switch array.

According to one embodiment of the signal conversion circuit of the present application, the smoothing filter module includes:
a fourth resistor; and
a capacitor, connected in parallel with the fourth resistor.

According to one embodiment of the signal conversion circuit of the present application, the transmission conversion module includes:
a second resistor unit;
an error amplifier unit including a first input terminal electrically connected to the output terminal of the smoothing filter module, and a second input terminal connected to the power supply via the second resistor unit;
a pass transistor including a first interface connected to an output terminal of the error amplifier unit, a second interface connected to the second input terminal of the error amplifier unit and connected to the power supply via the second resistor unit, and a third interface configured to output the first voltage signal and connected to a configuration channel (CC) pin of a Type-C interface;
a third resistor unit; and
a switching transistor including one terminal connected to the CC pin of the Type-C interface via the third resistor unit, and the other terminal grounded.

According to one embodiment of the signal conversion circuit of the present application, the signal amplitude calibration module includes:
a constant current source unit including one terminal electrically connected to the voltage-mode digital-to-analog conversion module, and the other terminal grounded; and
a current switch array, where each current switch unit in the current switch array includes a current source and a bilateral switch connected in series, and a plurality of the current switch units are connected to the constant current source unit in parallel.

According to a second aspect, the present application provides a transmitting method, including:
receiving a communication data signal sent from a USB PD protocol layer;
inputting the communication data signal into the signal conversion circuit as described in the first aspect, and receiving a BMC transmission signal output from the signal conversion circuit; and
transmitting the BMC transmission signal.

According to the transmitting method provided in the embodiments of the present application, by inputting the obtained communication data signal into the signal conversion circuit, the communication data signal can be processed into n delay control signals with a same time interval, and voltage values at several time points of the rising and falling edges of the signal can be set, so as to control the slope of the rising and falling edges in segments, so that the final output BMC transmission signal can meet the requirements of eye diagram compliance test and a slope for PD communication.

According to a third aspect, the present application provides a transmitting apparatus, including:
a first processing module, configured to receive a communication data signal sent from a USB PD protocol layer;
a second processing module, configured to input the communication data signal into the signal conversion circuit as described in the first aspect, and receive a BMC transmission signal output from the signal conversion circuit; and
a third processing module, configured to transmit the BMC transmission signal.

According to the transmitting apparatus provided in the embodiments of the present application, by inputting the obtained communication data signal into the signal conversion circuit, the communication data signal can be processed into n delay control signals with a same time interval, and voltage values at several time points of the rising and falling edges of the signal can be set, so as to control the slope of the rising and falling edges in segments, so that the final output BMC transmission signal can meet the requirements of eye diagram compliance test and a slope for PD communication.

According to a fourth aspect, the present application provides an electronic device, including a memory, a processor, and a computer program stored on the memory and executable on the processor. When the processor executes the computer program, the transmitting method as described in the second aspect is implemented.

According to a fifth aspect, the present application provides a non-transitory computer-readable storage medium on which a computer program is stored. When the computer program is executed by a processor, the transmitting method as described in the second aspect is implemented.

According to a sixth aspect, the present application provides a computer program product, including a computer program, where when executed by a processor, the computer program implements the transmitting method as described in the second aspect.

The foregoing one or more technical solutions in the embodiments of the present application have at least one of the following technical effects:

A communication data signal is converted into a plurality of delay control signals, which are further converted into stepwise ramp signals. In this way, a stepwise voltage and slope of the stepwise ramp signals can be adjusted based on actual needs, and a voltage amplitude of the BMC transmission signal can be adjusted based on the signal amplitude calibration module, such that a BMC signal can meet the requirements of eye diagram compliance test and a slope for PD communication. In addition, the signal conversion circuit features a low technical design barrier, offers flexible and simple debugging, and is easy to integrate on silicon wafers, without the need of any off-chip component, thus enhancing market applicability.

Further, by setting a plurality of flip-flops in the conversion timing generation module, the communication data signal can be converted into a plurality of delay signals, and output terminals of the plurality of flip-flops can be electrically connected to the input terminal of the logical combination unit, thereby converting the plurality of delay signals into a plurality of delay control signals based on the logical combination unit, and further adjusting the slope of the stepwise ramp signals based on the plurality of delay control signals, to meet the eye diagram compliance test for PD communication.

Furthermore, by setting a plurality of current switch units in the signal amplitude calibration module to be connected in parallel with the constant current source module, a suitable bias current can be provided to the voltage-mode digital-to-analog conversion module, different current combination paths can be selected to tune the bias current, thereby adjusting the amplitude of the BMC transmission signal to meet the requirements of the USB PD specification.

Furthermore, by inputting the obtained communication data signal into the signal conversion circuit, the communication data signal can be processed into n delay control signals with a same time interval, and voltage values at several time points of the rising and falling edges of the signal can be set, so as to control the slope of the rising and falling edges in segments, so that the final output BMC transmission signal can meet the requirements of eye diagram compliance test and a slope for PD communication.

Additional aspects and advantages of the present application will be partly provided in the following description, and partly become evident in the following description or understood through the practice of the present application.

### BRIEF DESCRIPTION OF THE DRAWINGS

The foregoing and/or additional aspects and advantages of the present application will become apparent and readily understood from the descriptions of the embodiments with reference to the following accompanying drawings, in which:

FIG. 1 is a first schematic structural diagram of a signal conversion circuit according to an embodiment of the present application;

FIG. 2 is a second schematic structural diagram of a signal conversion circuit according to an embodiment of the present application;

FIG. 3 is a principle diagram of a signal conversion circuit according to an embodiment of the present application;

FIG. 4 is a schematic flowchart of a transmitting method according to an embodiment of the present application;

FIG. 5 is a schematic structural diagram of a transmitting apparatus according to an embodiment of the present application;

FIG. 6 is a schematic structural diagram of an electronic device according to an embodiment of the present application.

### REFERENCE NUMERALS

Conversion timing generation module: 110; Signal amplitude calibration module: 120; Voltage-mode digital-to-analog conversion module: 130;

Smoothing filter module: 140; Transmission conversion module: 150; Flip-flop: D; Error amplifier unit: OP; Pass transistor: PM0; Switching transistor: NM0.

### DETAILED DESCRIPTION OF THE EMBODIMENTS

The technical solutions in the embodiments of this application are described below with reference to the accompanying drawings in the embodiments of this application. It is apparent that the described embodiments are merely some rather than all of the embodiments of this application. All other embodiments obtained by persons of ordinary skill in the art based on the described embodiments of this application shall fall within the protection scope of this application.

It should be noted that the terms “first”, “second”, and so on in the description and claims of the present disclosure are intended to distinguish between similar objects but do not necessarily indicate a specific order or sequence. It should be understood that data used in such a way may be interchanged under appropriate circumstances so that the embodiments of the present application can be implemented in an order other than those illustrated or described herein, the objects distinguished by “first”, “second”, etc. are usually of one type, and the number of objects is not limited. For example, one or more first objects may be provided. In addition, “and/or” in the specification and claims indicates at least one of the connected objects, and the character “/” generally indicates an “or” relationship between associated objects.

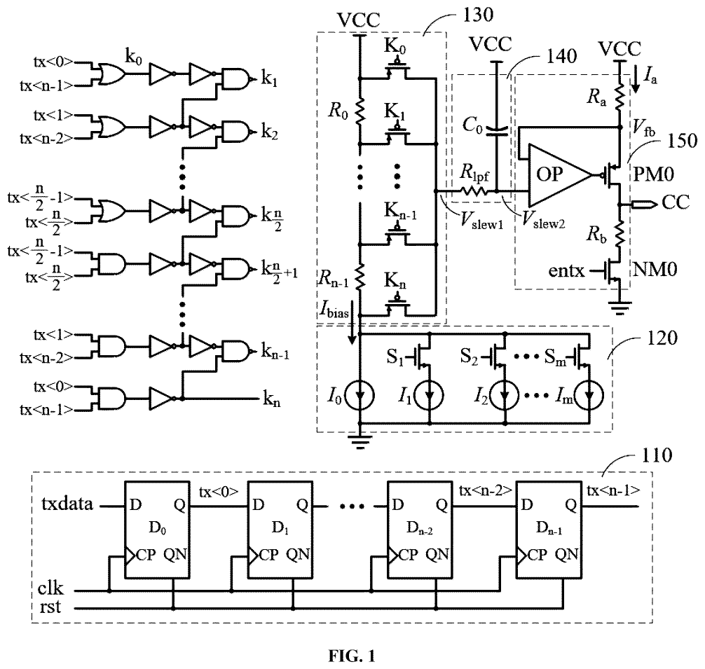

A signal conversion circuit provided in the embodiments of the present application will be described below in conjunction with FIGS. 1 to 3.

As shown in FIG. 1, the signal conversion circuit includes a conversion timing generation module 110, a signal amplitude calibration module 120, a voltage-mode digital-to-analog conversion module 130, a smoothing filter module 140, and a transmission conversion module 150.

In this embodiment, the conversion timing generation module 110 is configured to convert an input communication data signal into a plurality of delay control signals.

The conversion timing generation module 110 can receive a communication data signal, txdata, convert the signal txdata into n delay control signals, and send the n delay control signals to the voltage-mode digital-to-analog conversion module 130, where n is a positive integer greater than or equal to 2.

A time interval between any two adjacent delay control signals in the plurality of delay control signals is equal.

An input terminal of the voltage-mode digital-to-analog conversion module 130 is electrically connected to an output terminal of the conversion timing generation module 110, and the voltage-mode digital-to-analog conversion module 130 is electrically connected to the signal amplitude calibration module 120.

The voltage-mode digital-to-analog conversion module 130 is configured to convert the plurality of delay control signals into stepwise ramp signals.

The voltage-mode digital-to-analog conversion module 130 can receive a bias current output from the signal amplitude calibration module 120 and convert the plurality of delay control signals into the stepwise ramp signals based on the bias current.

A plurality of stepwise voltages corresponding to the stepwise ramp signals are not equal, and the stepwise voltages can be customized based on actual needs.

As shown in FIG. 3, the slope corresponding to the stepwise ramp signals can exhibit the following trend from left to right: gradually increasing from 0 to a certain degree and then decreasing to 0, and repeating this pattern of change.

An input terminal of the smoothing filter module 140 is electrically connected to an output terminal of the voltage-mode digital-to-analog conversion module 130.

The smoothing filter module 140 is configured to perform smoothing filtering processing on the stepwise ramp signals to obtain a first voltage signal.

The first voltage signal is obtained by subjecting the stepwise ramp signals to smoothing filtering processing.

The smoothing filter module 140 is configured to filter out ripple and step noise in the stepwise ramp signals to generate a smooth voltage signal, namely the first voltage signal.

An input terminal of the transmission conversion module 150 is electrically connected to an output terminal of the smoothing filter module 140.

The transmission conversion module 150 is configured to convert the first voltage signal into a BMC transmission signal.

BMC is acronym for Biphase Mark Coding.

The BMC transmission signal is a BMC-encoded transmission signal.

The USB PD (Fast Charging Standard for Universal Serial Bus) specification states that the CC pins of the Type-C interface are used as data transmission channels to negotiate the voltage, current, and power transmission direction during charging.

Based on the USB PD specification, BMC can be used for communication on the CC channels.

The signal amplitude calibration module 120 is configured to set a voltage amplitude of the BMC transmission signal.

Based on the USB PD specification, the amplitude of the BMC transmission signal is 1.125V, with a deviation range of (−75 mV, +75 mV). The signal amplitude calibration module 120 can adjust the voltage amplitude of the BMC transmission signal to a target value to meet the USB PD specification.

According to the signal conversion circuit of the embodiments in the present application, a communication data signal is converted into a plurality of delay control signals, which are further converted into stepwise ramp signals. In this way, a stepwise voltage and slope of the stepwise ramp signals can be adjusted based on actual needs, and a voltage amplitude of a BMC transmission signal can be adjusted based on the signal amplitude calibration module 120, such that a BMC signal can meet the requirements of eye diagram compliance test and a slope for PD communication. In addition, the signal conversion circuit features a low technical design barrier, offers flexible and simple debugging, and is easy to integrate on silicon wafers, without the need of any off-chip component, thus enhancing market applicability.

In some embodiments, the conversion timing generation module 110 may include: a plurality of flip-flops D and a logical combination unit.

In this embodiment, the plurality of flip-flops D are cascaded.

A first-stage flip-flop in the plurality of flip-flops D is configured to receive the communication data signal.

An input terminal of the logical combination unit is electrically connected to an output terminal of each flip-flop.

An output terminal of the logical combination unit is electrically connected to the input terminal of the voltage-mode digital-to-analog conversion module 130.

As shown in FIG. 1, the conversion timing generation module 110 may include n cascaded flip-flops (D₀-Dₙ₋₁), a D input of a first-stage flip-flop D₀ in the n cascaded flip-flops D is used to receive the communication data signal txdata, a Q output of the first-stage flip-flop D₀ is connected to a D input of a second-stage flip-flop D₁, a CP input of the first-stage flip-flop D₀ is connected to a delay clock signal clk, a QN output of the first-stage flip-flop D₀ is connected to a reset terminal rst, a Q output of an (n−1)th-stage flip-flop Dₙ₋₂ is connected to a D input of a last-stage flip-flop Dₙ₋₁, and outputs of the n flip-flops D are all used as inputs to the logical combination unit;

The logical combination unit can combine n delay signals tx<0: n−1> to obtain n delay control signals. The output terminal of the logical combination unit is electrically connected to the input terminal of the voltage-mode digital-to-analog conversion module 130.

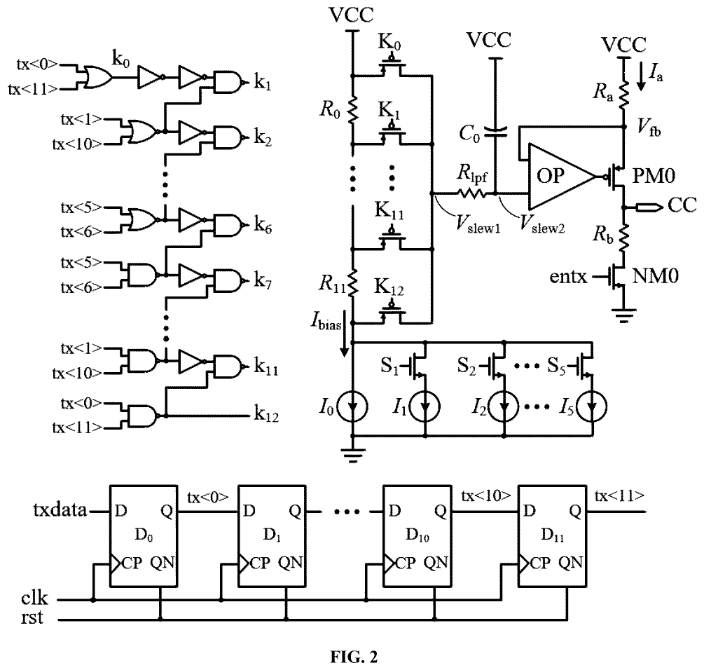

In the actual execution process, as shown in FIG. 2, 12 cascaded flip-flops D can be set in the conversion timing generation module 110. The D input of the first-stage flip-flop D₀ can receive the communication data signal txdata, and then process the communication data signal txdata into 12 delay signals tx<0:11> with equal time intervals. A period of the delay clock signal clk can be 50 ns, and the delay signals tx<0:11> are sent to the logical combination unit to obtain a plurality of delay control signals k₀-k₁₂. The waveforms of the delay control signals are shown in FIG. 3, and the plurality of delay control signals are output to the voltage-mode digital-to-analog conversion module 130.

According to the signal conversion circuit provided in the embodiments of the present application, by setting a plurality of flip-flops D in the conversion timing generation module 110, the communication data signal can be converted into a plurality of delay signals, and output terminals of the plurality of flip-flops can be electrically connected to the input terminal of the logical combination unit, thereby converting the plurality of delay signals into a plurality of delay control signals based on the logical combination unit, and further adjusting the slope of the stepwise ramp signals based on the plurality of delay control signals, to meet the eye diagram compliance test for PD communication.

In some embodiments, the voltage-mode digital-to-analog conversion module 130 may include: a series resistor array and a switch control unit.

In this embodiment, the series resistor array includes a first resistor array, as R₀-Rₙ₋₁ shown in FIG. 1.

The series resistor array includes an input terminal connected to a power supply VCC, and an output terminal electrically connected to an input terminal of signal amplitude calibration module 120.

The switch control unit includes a first switch array as K₀-Kₙ shown in FIG. 1.

An input terminal of the switch control unit is connected to one terminal of a first target switch in the first switch array, and the first target switch is the first switch in the first switch array, as K₀ shown in FIG. 1.

An output terminal of the switch control unit is connected to one terminal of a second target switch in the first switch array, and the second target switch is the last switch in the first switch array, as Kₙ shown in FIG. 1.

One terminal of a third target switch in the first switch array is connected to the smoothing filter module 140, and the other terminal of the third target switch is connected to a first target resistor in the first resistor array, the first target resistor is an nth resistor in the series resistor array, and the third target switch is an n-th switch in the switch control unit, where n is a positive integer. For example, in case that the first target resistor is R₀, the third target switch is K₁, at this time, one terminal of K₁ is connected to the smoothing filter module 140, and the other terminal of K₁ is connected to R₀.

The voltage-mode digital-to-analog conversion module 130 can control the working state of the first switch array based on the delay control signal, thereby controlling the operating state of each first resistor in the first resistor array, and obtaining stepwise ramp signals V_{slew1} with unequal stepwise voltages. For example, when the switch Kₙ₋₁ is closed, one terminal of Kₙ₋₁ is connected to the smoothing filter module 140, and the other terminal is connected to Rₙ₋₂.

In the actual implementation process, as shown in FIG. 2, the first resistor array can be set in the series resistor array. The first resistor array may include 12 first resistors R₀-R₁₁, and a resistance value of the first resistor can be set based on the stepwise voltage required by the stepwise ramp signals. The stepwise voltage can be represented by the following formula:

$$Δ {U}_{i} = {I}_{bias} \times {R}_{i} ,$$

where, ΔUᵢ is the stepwise voltage, I_{bias} is a combined current, and Rᵢ is an ith first resistor; I_{bias} is output from the signal amplitude calibration module 120 to the voltage-mode digital-to-analog conversion module 130; and

the operating state of the first switch array is controlled based on the delay control signal, and a plurality of first resistors R₀-R₁₁ with different resistance values are opened or closed one by one based on the operating state of the first switch array, thereby obtaining stepwise ramp signals V_{slew1} with unequal stepwise voltages. The waveforms of the stepwise ramp signals are shown in FIG. 3.

According to the signal conversion circuit provided in the embodiments of the present application, by setting the switch control unit in the voltage-mode digital-to-analog conversion module 130, the operating state of the first switch can be controlled based on the delay control signal generated by the conversion timing generation module 110, thereby controlling the operating state of the first resistor in the first resistor array to obtain stepwise ramp signals with unequal stepwise voltages, thus meeting the eye diagram compliance test for PD communication in practical applications.

In some embodiments, the smoothing filter module 140 may include a fourth resistor and a capacitor.

In this embodiment, the capacitor is connected in parallel with the fourth resistor.

The fourth resistor R_{ipf} includes one terminal connected to the voltage-mode digital-to-analog conversion module 130 and the other terminal connected to the capacitor Co and the transmission conversion module 150.

The capacitor Co includes one terminal connected to the fourth resistor R_{ipf} and the other terminal connected to the power supply VCC.

The stepwise ramp signals V_{slew1} generated by the voltage-mode digital-to-analog conversion module 130 can be converted into a smooth voltage signal, namely the first voltage signal V_{slew2}, through Resistance-Capacitance (RC) Filtering.

According to the signal conversion circuit provided in the embodiments of the present application, by setting the smoothing filter module 140 as a parallel circuit including the fourth resistor and the capacitor, the stepwise ramp signals can be converted into the first voltage signal under the filtering effect, which can filter out interference signals in the stepwise ramp signals and improve the accuracy of the final output signal.

In some embodiments, the signal amplitude calibration module 120 may include: a constant current source unit and a current switch array.

In this embodiment, the constant current source unit includes one terminal electrically connected to the voltage-mode digital-to-analog conversion module 130, and the other terminal grounded.

Each current switch unit in the current switch array includes a current source and a bilateral switch connected in series, and a plurality of the current switch units are connected to the constant current source unit in parallel.

As shown in FIG. 1, when each of the bilateral switch S₁-Sₘ is closed, a corresponding current source I₁-Iₘ is activated, and when each of the bilateral switch S₁-Sₘ is open, the corresponding current source I₁-Iₘ is disabled, where m is an integer greater than or equal to 2.

In the actual implementation process, as shown in FIG. 2, 5 current switch units may be set. In case that the bilateral switch S₁-S₅ is closed, the current source I₁-I₅ is activated, and when each of the bilateral switch S₁-S₅ is open, the current source I₁-I₅ is disabled. One terminal of each current source is electrically connected to the voltage-mode digital-to-analog conversion module 130, so as to provide a combined current I_{bias} to the voltage-mode digital-to-analog conversion module.

In the signal conversion circuit according to the embodiments of the present application, the signal amplitude calibration module 120 includes a current switch array arranged in parallel with the constant current source module. This configuration provides an appropriate bias current to the voltage-mode digital-to-analog conversion module 130. By selecting different current combination paths, the bias current can be precisely tuned, thereby adjusting the amplitude of the BMC transmission signal to meet the requirements of the USB PD specification.

In some embodiments, the transmission conversion module 150 may include:

An error amplifier unit OP, a pass transistor PM0, a second resistor unit; a third resistor unit; and a switching transistor NM0.

In this embodiment, the error amplifier unit OP includes a first input terminal electrically connected to the output terminal of the smoothing filter module 140, and a second input terminal connected to the power supply via the second resistor unit.

The pass transistor PM0 includes a first interface connected to an output terminal of the error amplifier unit OP, a second interface connected to the second input terminal of the error amplifier unit OP and connected to the power supply via the second resistor, and a third interface configured to output the first voltage signal and connected to a CC pin of a Type-C interface.

The second resistor unit is configured to convert the first voltage signal received by the transmission conversion module 150 into a current signal.

The second resistor unit includes one terminal connected to the power supply, and the other terminal electrically connected to the third interface of the pass transistor PM0.

After the current signal flows through the third resistor unit, the BMC transmission signal can be obtained.

The switching transistor NM0 includes one terminal connected to the CC pin of the Type-C interface via the third resistor unit, and the other terminal grounded.

In case that the switching transistor NM0 is turned on, the BMC transmission signal is sent to the CC line; in case that the switching transistor NM0 is turned off, the BMC transmission signal is not sent, and the CC line is capable of performing Attach/Detach detection and receive signals sent from other devices.

In the actual implementation process, as shown in FIG. 2, the first voltage signal V_{slew2} is converted into the smooth current signal based on the following formula:

$${I}_{a} = \frac{VCC - {V}_{fb}}{{R}_{a}} ,$$

where, Iₐ is the current signal, VCC is a power supply voltage, V_{fb} is the first voltage signal, and based on the virtual short principle of an operational amplifier, V_{fb}=V_{slew2}, and Ra is the second resistor unit.

The resistance value of the third resistor unit R_{b} can be set within the range of 3362-7562. For example, the resistance value of the third resistor unit R_{b} can be set to 5052, and then the BMC transmission signal can be obtained based on the following formula:

$${U}_{BMC} = {I}_{a} \times {R}_{b} ,$$

where, U_{BMC} is the BMC transmission signal, la is the current signal, R_{b} is the third resistor unit.

The waveform of the obtained BMC transmission signal is shown in FIG. 3.

According to the signal conversion circuit provided in the embodiments of the present application, by setting the resistance value of the third resistor unit in the transmission conversion module 150 is configured to achieve impedance matching with the transmission line. Consequently, the final output BMC transmission signal is capable of meeting the eye diagram compliance test for PD communication. In addition, the switching transistor NM0 is integrated within the transmission conversion module 150, allowing it to be disconnected without the need to transmit a BMC transmission signal. This design ensures no interference with the Attach/Detach detection on the CC line or the reception of the BMC transmission signal transmitted from other devices.

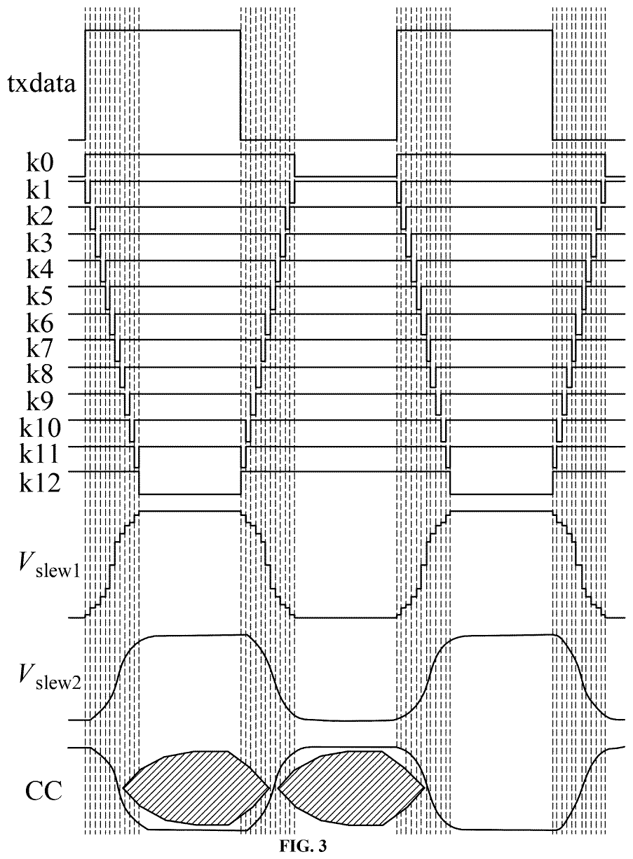

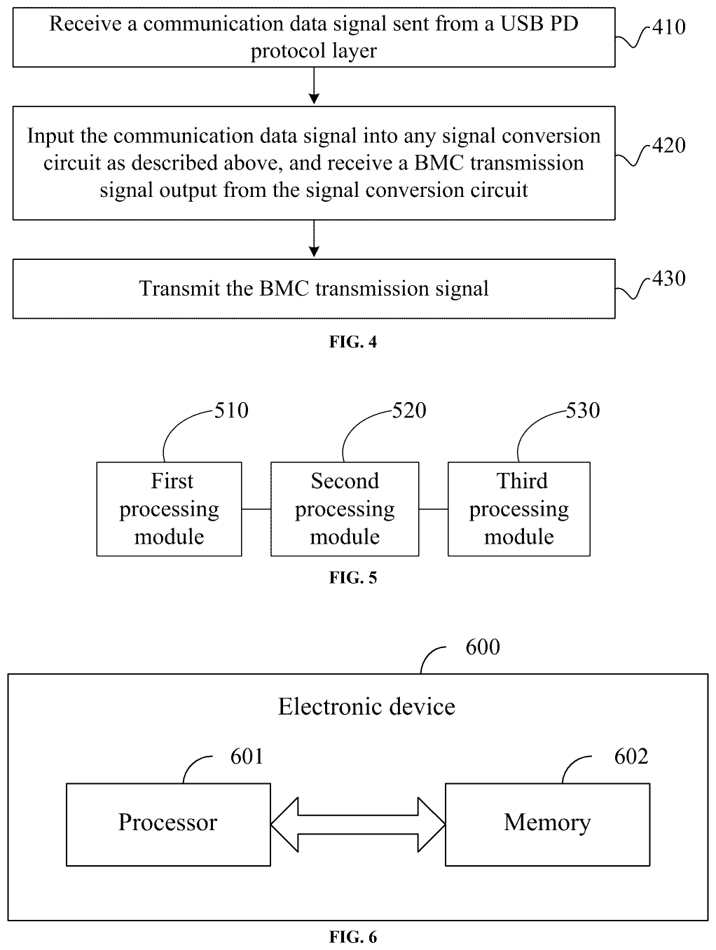

A transmitting method provided in the embodiments of the present application will be described below in conjunction with FIG. 4.

It should be noted that the executing entity of the transmitting method can be a server, a transmitting apparatus, or a user's terminal, including but not limited to mobile terminals and non mobile terminals.

For example, mobile terminals include but are not limited to mobile phones, personal digital assistant (PDA) smart terminals, tablets, and vehicle-mounted smart terminals; and non mobile terminals include but are not limited to PC terminals.

As shown in FIG. 4, the transmitting method includes step 410, step 420, and step 430.

Step 410. Receive a communication data signal sent from a USB PD protocol layer.

Step 420. Input the communication data signal into the signal conversion circuit as described in any of the above embodiments, and receive a BMC transmission signal output from the signal conversion circuit.

Step 430. Transmit the BMC transmission signal.

In this embodiment, the USB PD specification can use the CC pins of the Type-C interface as data transmission channels to negotiate the voltage, current, and power transmission direction for charging.

Based on the USB PD specification, BMC can be used for communication on the CC.

According to the transmitting method provided in the embodiments of the present application, by inputting the received communication data signal into the signal conversion circuit, the communication data signal can be processed into n delay control signals with equal time intervals, and voltage values at several time points of the rising and falling edges of the signal can be set, so as to control the slope of the rising and falling edges in segments, so that the final output BMC transmission signal can meet the requirements of eye diagram compliance test and a slope for PD communication.

The following describes a transmitting apparatus provided in the present application. The transmitting apparatus described below and the transmitting method described above can be cross-referenced.

The transmitting method provided in the embodiments of the present application can be executed by the transmitting apparatus. Taking the example of the transmitting method executed by the transmitting apparatus in the embodiments of the present application, the transmitting apparatus provided in the embodiments of the present application is explained.

An embodiment of the present application further provides a transmitting apparatus.

As shown in FIG. 5, the transmitting apparatus may include a first processing module 510, a second processing module 520, and a third processing module 530.

The first processing module 510 is configured to receive a communication data signal sent from a USB PD protocol layer;
the second processing module 520 is configured to input the communication data signal into the signal conversion circuit as described in any of the above embodiments, and receive a BMC transmission signal output from the signal conversion circuit; and
the third processing module 530 is configured to transmit the BMC transmission signal.

According to the transmitting apparatus of the embodiments of the present application is configured to obtained a communication data signal and process it through the signal conversion circuit. This circuit generates n delay control signals with equal time intervals, and allows setting voltage levels at multiple sampling points along the rising and falling edges of the signal. As a result, the slope of the rising and falling edges can be controlled in segments, enabling the final output BMC transmission signal to meet the requirements of eye diagram compliance test and a slope for PD communication.

The transmitting apparatus in this embodiment of the present application can be an electronic device or a component of an electronic device, such as an integrated circuit or chip. The electronic device can be a terminal or other devices besides the terminal. For example, the electronic devices can include mobile phones, tablets, laptops, handheld computers, vehicle-mounted electronic devices, mobile internet devices (MIDs), augmented reality (AR)/virtual reality (VR) devices, robots, wearable devices, ultra-mobile personal computers (UMPCs), netbooks, or PDAs, as well as servers, network attached storage (NAS), personal computers (PCs), televisions (TVs), ATMs, or self-service machines. The embodiments of the present application are not specifically limited.

The transmitting apparatus in this embodiment of the present application can be a device with an operating system. The operating system can be the Android operating system, the iOS operating system, or any other possible operating system, and the embodiments of the present application are not specifically limited.

The transmitting apparatus provided in this embodiment of the present application can implement various processes of the method embodiment shown in FIG. 4. To avoid repetition, it will not be repeated here.

In some embodiments, as shown in FIG. 6, the present application also provides an electronic device 600, including a processor 601, a memory 602, and a computer program stored on the memory 602 and executable on the processor 601. When the program is executed by the processor 601, the various processes of the above transmitting method embodiments are implemented and the same technical effect is achieved. To avoid repetition, it will not be repeated here.

It should be noted that the electronic devices in the embodiments of the present application include the mobile electronic devices and non mobile electronic devices described above.

In another aspect, the present application also provides a computer program product including a computer program stored on a non transient computer-readable storage medium, where the computer program includes program instructions. When the program instructions are executed by a computer, the computer can perform various processes of the above-mentioned transmitting method embodiments and achieve the same technical effects. To avoid repetition, they will not be repeated here.

In another aspect, the present application also provides a non-transitory computer-readable storage medium, on which a computer program is stored. When the computer program is executed by a processor, the various processes of the above-mentioned transmitting method embodiments are implemented and the same technical effects are achieved. To avoid repetition, it will not be repeated here.

In another aspect, the embodiments of the present application provide another chip, which includes a processor and a communication interface. The communication interface is coupled to the processor, and the processor is used to run programs or instructions to implement the various processes of the above-mentioned transmitting method embodiments, and can achieve the same technical effects. To avoid repetition, it will not be repeated here.

It should be understood that the chips mentioned in the embodiments of the present application can also be referred to as system-level chips, system chips, chip systems, or on-chip system chips, etc.

The device embodiment described above is merely schematic, where the unit described as a separate component may or may not be physically separated, and a component displayed as a unit may or may not be a physical unit, that is, the component may be located at one place, or distributed on a plurality of network units. Some or all of the modules may be selected based on actual needs to achieve the objectives of the solutions of the embodiments. A person of ordinary skill in the art can understand and implement the embodiments without creative efforts.

Through the description of the foregoing implementations, a person skilled in the art can clearly understand that the implementations can be implemented by means of software plus a necessary universal hardware platform, or certainly, can be implemented by hardware. Based on such understanding, the foregoing technical solution which is essential or a part contributing to the prior art may be embodied in the form of a software product, the computer software product may be stored in a computer readable storage medium, such as an ROM/RAM, a magnetic disk or an optical disk, including a plurality of instructions for causing a computer device (which may be a personal computer, a server, or a network device) to perform the methods described in the examples or some parts of the examples.

Finally, it should be noted that the foregoing embodiments are merely used to explain the technical solutions of the present invention, but are not intended to limit the same. Although the present invention is described in detail with reference to the foregoing embodiments, those of ordinary skill in the art should understand that they can still modify the technical solutions described in the foregoing embodiments, or make equivalent substitutions on some technical features therein. These modifications or substitutions do not make the essence of the corresponding technical solutions deviate from the spirit and scope of the technical solutions of the embodiments of the present invention.

What is claimed is:

1. A signal conversion circuit, comprising:
a conversion timing generation module, configured to convert an input communication data signal into a plurality of delay control signals;
a signal amplitude calibration module;
a voltage-mode digital-to-analog conversion module, wherein an input terminal of the voltage-mode digital-to-analog conversion module is electrically connected to an output terminal of the conversion timing generation module, and the voltage-mode digital-to-analog conversion module is electrically connected to the signal amplitude calibration module and configured to convert the plurality of delay control signals into stepwise ramp signals;
a smoothing filter module, wherein an input terminal of the smoothing filter module is electrically connected to an output terminal of the voltage-mode digital-to-analog conversion module; and the smoothing filter module is configured to perform smoothing filtering processing on the stepwise ramp signals to obtain a first voltage signal; and
a transmission conversion module, wherein an input terminal of the transmission conversion module is electrically connected to an output terminal of the smoothing filter module; and the transmission conversion module is configured to convert the first voltage signal into a biphase mark coding (BMC) transmission signal.

2. The signal conversion circuit according to claim 1, wherein the conversion timing generation module comprises:
a plurality of cascaded flip-flops, wherein a first-stage flip-flop in the plurality of flip-flops is configured to receive the communication data signal; and
a logical combination unit comprising an input terminal electrically connected to an output terminal of each of the flip-flops, and an output terminal electrically connected to the input terminal of the voltage-mode digital-to-analog conversion module.

3. The signal conversion circuit according to claim 1, wherein the voltage-mode digital-to-analog conversion module comprises:
a series resistor array comprising a first resistor array, wherein the series resistor array comprises an input terminal connected to a power supply, and an output terminal electrically connected to an input terminal of the signal amplitude calibration module; and
a switch control unit comprising a first switch array, wherein a first target switch in the first switch array comprises one terminal connected to the power supply and the other terminal connected to the smoothing filter module, a second target switch in the first switch array comprises one terminal connected to the output terminal of the series resistor array and the other terminal connected to the smoothing filter module, and a third target switch in the first switch array comprises one terminal connected to the smoothing filter module and the other terminal connected to a first target resistor in the first resistor array, wherein the first target resistor is an nth resistor in the series resistor array, the third target switch is an n-th switch in the switch control unit, n is a positive integer, the first target switch is a first switch in the first switch array, and the second target switch is a last switch in the first switch array.

4. The signal conversion circuit according to claim 1, wherein the smoothing filter module comprises:
a fourth resistor; and
a capacitor, connected in parallel with the fourth resistor.

5. The signal conversion circuit according to claim 4, wherein the transmission conversion module comprises:
a second resistor unit;
an error amplifier unit comprising a first input terminal electrically connected to the output terminal of the smoothing filter module, and a second input terminal connected to the power supply via the second resistor unit;
a pass transistor comprising a first interface connected to an output terminal of the error amplifier unit, a second interface connected to the second input terminal of the error amplifier unit and connected to the power supply via the second resistor unit, and a third interface configured to output the first voltage signal and connected to a configuration channel (CC) pin of a Type-C interface;
a third resistor unit; and
a switching transistor comprising one terminal connected to the CC pin of the Type-C interface via the third resistor unit, and the other terminal grounded.

6. The signal conversion circuit according to claim 1, wherein the signal amplitude calibration module comprises:
a constant current source unit comprising one terminal electrically connected to the voltage-mode digital-to-analog conversion module, and the other terminal grounded; and
a current switch array, wherein each current switch unit in the current switch array comprises a current source and a bilateral switch connected in series, and a plurality of the current switch units are connected to the constant current source unit in parallel.

7. A transmitting method, comprising:
receiving a communication data signal sent from a universal serial bus power delivery (USB PD) protocol layer;
inputting the communication data signal into the signal conversion circuit according to claim 1, and receiving a BMC transmission signal output from the signal conversion circuit; and
transmitting the BMC transmission signal.

8. A transmitting apparatus, comprising:
a first processing module, configured to receive a communication data signal sent from a USB PD protocol layer;
a second processing module, configured to input the communication data signal into the signal conversion circuit according to claim 1, and receive a BMC transmission signal output from the signal conversion circuit; and
a third processing module, configured to transmit the BMC transmission signal.

9. An electronic device, comprising a memory, a processor, and a computer program stored in the memory and operable on the processor, wherein the processor, when executing the program, implements the transmitting method according to claim 7.

10. A non-transitory computer-readable storage medium, storing a computer program thereon, wherein when the computer program is executed by a processor, the transmitting method according to claim 7 is implemented.

11. A chip, comprising a processor and a communication interface, wherein the communication interface is coupled to the processor, and the processor is configured to run programs or instructions to implement the transmitting method according to claim 7.

12. The signal conversion circuit according to claim 2, wherein the voltage-mode digital-to-analog conversion module comprises:
a series resistor array comprising a first resistor array, wherein the series resistor array comprises an input terminal connected to a power supply, and an output terminal electrically connected to an input terminal of the signal amplitude calibration module; and
a switch control unit comprising a first switch array, wherein a first target switch in the first switch array comprises one terminal connected to the power supply and the other terminal connected to the smoothing filter module, a second target switch in the first switch array comprises one terminal connected to the output terminal of the series resistor array and the other terminal connected to the smoothing filter module, and a third target switch in the first switch array comprises one terminal connected to the smoothing filter module and the other terminal connected to a first target resistor in the first resistor array, wherein the first target resistor is an nth resistor in the series resistor array, the third target switch is an n-th switch in the switch control unit, n is a positive integer, the first target switch is a first switch in the first switch array, and the second target switch is a last switch in the first switch array.

13. The signal conversion circuit according to claim 2, wherein the smoothing filter module comprises:
a fourth resistor; and
a capacitor, connected in parallel with the fourth resistor.

14. The signal conversion circuit according to claim 3, wherein the smoothing filter module comprises:
a fourth resistor; and
a capacitor, connected in parallel with the fourth resistor.

15. The signal conversion circuit according to claim 12, wherein the smoothing filter module comprises:
a fourth resistor; and
a capacitor, connected in parallel with the fourth resistor.

16. The signal conversion circuit according to claim 12, wherein the transmission conversion module comprises:
a second resistor unit;
an error amplifier unit comprising a first input terminal electrically connected to the output terminal of the smoothing filter module, and a second input terminal connected to the power supply via the second resistor unit;
a pass transistor comprising a first interface connected to an output terminal of the error amplifier unit, a second interface connected to the second input terminal of the error amplifier unit and connected to the power supply via the second resistor unit, and a third interface configured to output the first voltage signal and connected to a configuration channel (CC) pin of a Type-C interface;
a third resistor unit; and
a switching transistor comprising one terminal connected to the CC pin of the Type-C interface via the third resistor unit, and the other terminal grounded.

17. The signal conversion circuit according to claim 2, wherein the signal amplitude calibration module comprises:
a constant current source unit comprising one terminal electrically connected to the voltage-mode digital-to-analog conversion module, and the other terminal grounded; and
a current switch array, wherein each current switch unit in the current switch array comprises a current source and a bilateral switch connected in series, and a plurality of the current switch units are connected to the constant current source unit in parallel.

18. The signal conversion circuit according to claim 3, wherein the signal amplitude calibration module comprises:
a constant current source unit comprising one terminal electrically connected to the voltage-mode digital-to-analog conversion module, and the other terminal grounded; and
a current switch array, wherein each current switch unit in the current switch array comprises a current source and a bilateral switch connected in series, and a plurality of the current switch units are connected to the constant current source unit in parallel.

19. The signal conversion circuit according to claim 4, wherein the signal amplitude calibration module comprises:
a constant current source unit comprising one terminal electrically connected to the voltage-mode digital-to-analog conversion module, and the other terminal grounded; and
a current switch array, wherein each current switch unit in the current switch array comprises a current source and a bilateral switch connected in series, and a plurality of the current switch units are connected to the constant current source unit in parallel.

20. The signal conversion circuit according to claim 5, wherein the signal amplitude calibration module comprises:
a constant current source unit comprising one terminal electrically connected to the voltage-mode digital-to-analog conversion module, and the other terminal grounded; and
a current switch array, wherein each current switch unit in the current switch array comprises a current source and a bilateral switch connected in series, and a plurality of the current switch units are connected to the constant current source unit in parallel.
